(19) United States
(12) Patent Application Publication
(10) Pub. No.: US 2026/0107788 A1
(43) Pub. Date: Apr. 16, 2026

(54) LEADFRAME BASED SEMICONDUCTOR PACKAGE WITH MULTIPLE DEVICES

(71) Applicant: TEXAS INSTRUMENTS INCORPORATED, Dallas, TX (US)

(72) Inventors: Jie Chen, Plano, TX (US); Satyendra S. Chauhan, Murphy, TX (US); Rajen Manicon Murugan, Dallas, TX (US); Sylvester Ankamah-Kusi, Mckinney, TX (US); Harshpreet Singh Phull Bakshi, Dallas, TX (US)

(21) Appl. No.: 19/318,224

(22) Filed: Sep. 3, 2025

Related U.S. Application Data
(60) Provisional application No. 63/707,844, filed on Oct. 16, 2024.

(51) Int. Cl. H01L 23/495; H01L 23/00; H01L 23/31

(52) U.S. Cl. CPC H10W 70/481; H10W 70/465; H10W 70/475; H10W 74/111; H10W 72/07236; H10W 90/726

(57) ABSTRACT

A semiconductor package includes a plurality of leads, each lead having a planar portion and a non-planar portion, in which: the planar portion has a first side and a second side opposing the first side, and the non-planar portion is at an angle with the planar portion. The semiconductor package includes a first device mechanically coupled to the first side of the planar portion with first interconnects and a second device mechanically coupled to the second side of the planar portion with second interconnects. The semiconductor package includes mold compound covering the first device and the second device, in which: a first mold overlay is on a side of the first device distant from the leads, and a second mold overlay is on a side of the second device distant from to the leads.

### CROSS REFERENCE TO RELATED APPLICATIONS

This application claims the benefit of priority to U.S. Provisional Patent Application Ser. No. 63/707,844 filed on Oct. 16, 2024, entitled “ESOT-PASSIVE MODULE ON FCSOT.” The disclosure of the prior application is considered part of and is hereby incorporated by reference in its entirety in the disclosure of this Application.

### BACKGROUND

Semiconductor packages provide electrical and thermo-mechanical support for an integrated circuit (IC) die, enabling it to be connected to printed wiring boards with appropriate conductive interconnects. Such semiconductor packages are available in many different configurations, one of which is a leadframe based package, such as a Small Outline Transistor (SOT) package. A typical leadframe is die-stamped from a sheet of flat-stock metal, and includes a plurality of metal leads (also called bond fingers) temporarily held together in a planar arrangement around a central region by a rectangular frame. A mounting pad for the semiconductor die is supported in the central region by “tie bars” that attach to the frame. In some packages, the central die pad is absent, and the semiconductor die is directly bonded to the leads.

### SUMMARY

In an example, a semiconductor package includes a plurality of leads, each lead having a planar portion and a non-planar portion. The planar portion has a first side and an opposing second side, and the non-planar portion is at an angle with the planar portion. A passive module is mechanically coupled to the first side of the planar portion with first interconnects; a semiconductor die is mechanically coupled to the second side of the planar portion with second interconnects; and mold compound covers (e.g., encapsulates) the passive module and the semiconductor die in the semiconductor package. A first mold overlay is on a side of the passive module distant from the leads, and a second mold overlay is on a side of the semiconductor die distant from to the leads.

In another example, a semiconductor package includes a leadframe comprising a plurality of leads, each lead having a planar portion and a non-planar portion. The planar portion has a first side and an opposing second side, and the non-planar portion is at an angle with the planar portion, A first device is mechanically coupled to the first side of the planar portion with first interconnects of a first material, and a second device is mechanically coupled to the second side of the planar portion with second interconnects of a second material different from the first material. A mold compound covers the first device and the second device inside the semiconductor package.

In another example, a method for making a semiconductor package includes dispensing (e.g., plating and bumping, depositing, screen printing, etc.) solder of a first solder type on first bond-pads of a first device; placing the first device on a first side of a leadframe such that the first bond-pads align with a first subset of leads of the leadframe; subjecting the leadframe and the first device to a first solder reflow process at a first temperature such that the first device is mechanically attached to the first side of the leadframe; turning the leadframe to expose a second side of the leadframe opposite to the first side; dispensing (e.g., plating and bumping, depositing, screen printing, etc.) solder of a second solder type on second bond-pads of a second device; placing the second device on the second side of the leadframe such that the second bond-pads align with a second subset of the leads; and subjecting the leadframe, the first device and the second device to a second solder reflow process at a second temperature to generate a leadframe assembly, wherein the second device is mechanically attached to the second side of the leadframe without affecting the first device.

### BRIEF DESCRIPTION OF THE DRAWINGS

Examples will be readily understood by the following detailed description in conjunction with the accompanying drawings. To facilitate this description, like reference numerals designate like elements. Aspects are illustrated by way of example, and not by way of limitation, in the figures of the accompanying drawings.

FIG. 1 is a simplified diagram illustrating a cross-sectional view of an example semiconductor package with devices on either side of the leadframe.

FIG. 2 is a simplified diagram illustrating a cross-sectional view of an example semiconductor package with devices on either side of the leadframe.

FIG. 3 is a simplified diagram illustrating a cross-sectional view of an example semiconductor package with devices on either side of the leadframe.

FIGS. 4A and 4B are simplified diagrams illustrating a cross-sectional view and plan view of portions of an example semiconductor package with devices on either side of the leadframe.

FIG. 5 is a simplified diagram illustrating a plan view of an example semiconductor package with devices on either side of the leadframe.

FIG. 6 is a simplified diagram illustrating a plan view of an example semiconductor package with devices on either side of the leadframe.

FIG. 7 is a simplified diagram illustrating a plan view of an example semiconductor package with devices on either side of the leadframe.

FIG. 8 is a simplified flow diagram illustrating example operations associated with making an example semiconductor package with devices on either side of the leadframe.

FIG. 9 is a simplified flow diagram illustrating example operations associated with making an example semiconductor package with devices on either side of the leadframe.

FIG. 10 is a simplified diagram illustrating a cross-sectional view of an example semiconductor package with devices on the same side of the leadframe.

FIG. 11 is a simplified diagram illustrating a cross-sectional view of another example semiconductor package with devices on the same side of the leadframe.

### DETAILED DESCRIPTION

For purposes of illustrating the examples described herein, it is important to understand certain terminology and operations of semiconductor packages. The following foundational information may be viewed as a basis from which various technical aspects described in the present disclosure may be properly explained. Such information is offered for purposes of explanation only and, accordingly, should not be construed in any way to limit the broad scope of the technology presented herein and its potential applications.

In the following detailed description, various aspects of the illustrative implementations may be described using terms commonly employed by those skilled in the art to convey the substance of their work to others skilled in the art.

The term “integrated circuit” (also referred to as IC) means a circuit that is integrated into a monolithic semiconductor or analogous material. A “die” or “semiconductor die” refers to a piece of semiconductor or analogous material (e.g., silicon, gallium nitride, etc.), that contains an IC or other electronic components. The terms “package” and “semiconductor package” are synonymous, as are the terms “die” and “semiconductor die.”

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “connected” means a direct connection (which may be one or more of a physical, electrically conductive, and/or thermal connection) between the things that are connected, without any intermediary devices, while the term “coupled” means either a direct connection between the things that are connected, or an indirect connection through one or more passive or active intermediary devices.

In a general sense, an “interconnect” refers to any element that provides a physical connection between two other elements. In the context of the examples described herein, the interconnects provide electrical connectivity between two electrical components, facilitating communication of electrical signals between them. Examples of such interconnects include solder balls (e.g., flip chips), copper pillars, conductive traces, wires (including wirebonds and wedge bonds thereof), bond pads, conductive vias, etc.

The term “package substrate” or “substrate” is used to describe any substrate material that facilitates the packaging together of any collection of semiconductor dies and/or other electrical components such as passive electrical components. As used herein, a package substrate is formed of any material including, but not limited to, insulating materials such as resin impregnated glass fibers (e.g., PCB), glass, ceramic, silicon, silicon carbide, aluminum nitride, alumina, etc. In addition, as used herein, a package substrate may refer to a substrate that includes buildup layers (e.g., ABF layers). Further, the package substrate may comprise a conductive leadframe with leads. In yet other examples, the substrate may comprise disjointed conductive pieces (e.g., die pad, bond-pads, leads, etc.) enmeshed in a dielectric material, such as mold compound and polyimide films. Packages may also include organic or inorganic passivation layers between the bare die and the substrate.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The accompanying drawings are not necessarily drawn to scale. In the drawings, the singular and plural forms of the labels may be used with reference numerals to denote a single one and multiple ones respectively of the same or analogous type, species, or class of element. Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using suitable characterization tools. In such images of real structures, possible processing and/or surface defects could also be visible, e.g., surface roughness, curvature or profile deviation, pit or scratches, not-perfectly straight edges of materials, tapered vias or other openings, and/or inadvertent rounding of corners or variations in thicknesses of different material layers. There may be other defects not listed here but that are common within the field of packaging. All such non-idealized and realistic possibilities are intended to be included in the scope of the various examples described herein.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to electrical connectivity, or thermal mitigation). Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments. Note also that in cross-sectional views, some interconnects shown as touching each other need not touch each other at all; they may be in different planes with intervening material removed. Thus, unless specifically described as being d, surfaces shown to be touching each other may, in fact, have intervening material that is not shown for ease of illustration. Further, unless otherwise specified, the structures shown in the figures may take any suitable form or shape according to material properties, fabrication processes, and operating conditions.

Fast switching power metal-oxide-semiconductor field-effect transistors (MOSFETs) create high current and voltage transients that impact performance. The voltage ripple created by the switching behavior can stress the FET, reduce device reliability, and exacerbate emissions. Power devices targeted for automotive and industrial markets have to meet stringent Electromagnetic Compatibility (EMC) directives imposed by international standards and Original Equipment Manufacturer (OEMs). Passive devices such as capacitors and inductors are usually used with such semiconductor devices to minimize emissions, and to meet compliance standards. In many currently available electronic systems, these passive devices are placed on the electronic boards on which the power devices are mounted. When the passive devices are placed outside of the semiconductor package, the electrical connection to the die can add electrical parasitics through increased resistance (R) and inductance (L). For example, the Rand L increase includes the routing on the printed circuit board (PCB) and the routing within the package (e.g., for SOT package, such routing includes the gull-wing leads).

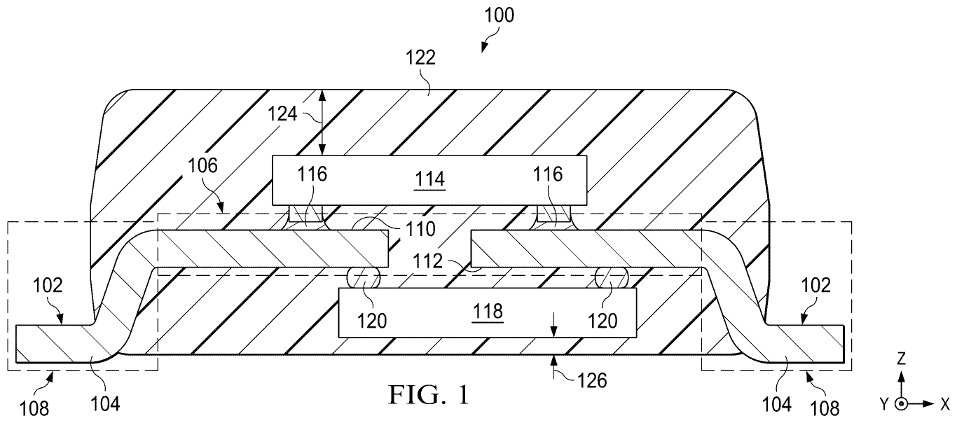

FIG. 1 is a simplified diagram illustrating a cross-sectional view of an example semiconductor package 100. Semiconductor package 100 includes a leadframe 102 comprising a plurality of leads, each lead 104 having a planar portion 106 and a non-planar portion 108. Leadframe 102 comprises conductive material, such as copper or other metals in some examples. Planar portion 106 has a first side 110 and an opposing second side 112, and non-planar portion 108 is at an angle with (e.g., bent away from) planar portion 106. A first device 114 is mechanically coupled to first side 110 of planar portion 106 with first interconnects 116. A second device 118 is mechanically coupled to second side 112 of planar portion 106 with second interconnects 120. In some examples, first device 114 is electrically coupled to second device 118 through leadframe 102. For example, a continuous electrically conductive path is realized between first device 114 and second device 118 through first interconnects 116, leads 104 and second interconnects 120. Although not shown so as not to clutter the drawings, first interconnects 116 and second interconnects 120 include bond-pads on respective first device 114 and second device 118.

A mold compound 122 covers (e.g., encapsulates) first device 114 and second device 118 inside semiconductor package 100 such that a first mold overlay 124 is on a side of first device 114 distant from leads 104, and a second mold overlay 126 is on a side of second device 118 distant from leads 104. For example, neither first device 114 nor second device 118 is visible outside semiconductor package 100. First mold overlay 124 and second mold overlay 126 ensures that first device 114 and second device 118 are entirely enclosed by mold compound 122. In the example shown, semiconductor package 100 is a flip-chip small outline package (FCSOT). Other types of leadframe based packages may be included in the broad scope of the various modifications to the illustrated example.

In various examples, first device 114 and second device 118 comprise active circuits therein. The term “active circuit” refers to a circuit that contains active components—such as transistors, diodes, or other semiconductor devices—that are capable of controlling the flow of current through the circuit. These active components typically require an external power supply and can amplify signals, generate oscillations, or perform other functions that passive components (such as resistors, capacitors, and inductors) cannot. In some other examples, first device 114 comprises one or more active circuits, whereas second device 118 does not comprise any active circuits (e.g., first device 114 comprises a power MOSFET and second device 118 comprises at least a capacitor and/or an inductor). In yet other examples, first device 114 does not comprise any active circuits, whereas second device 118 comprises at least one active circuit.

In some examples, first interconnects 116 and second interconnects 120 comprise flip chip interconnects, such as solder balls. In some other examples, first interconnects 116 and second interconnects 120 comprise copper pillars with solder caps. In some other examples, first interconnects 116 and second interconnects 120 comprise copper pillars without solder caps (e.g., copper to copper thermo-compression bonds). In some other examples, first interconnects 116 comprise flip chip interconnects whereas second interconnects 120 comprise copper pillars with solder caps or copper pillars without solder caps and vice versa. In various examples, first interconnects 116 and second interconnects 120 are not wirebonds. In some other examples, first interconnects 116 and/or second interconnects 120 are wirebonds. Various other types of die-to-package interconnections may be used in first interconnects 116 and second interconnects 120 within the broad scope of the examples discussed herein.

In some examples, first device 114 is larger than second device 118 in a top view. In other examples, second device 118 is larger than first device 114 in a top view. In some examples, first device 114 is thicker than second device 118 in a cross-section view. In other examples, second device 118 is thicker than first device 114 in a cross-section view. In some examples, first mold overlay 124 is smaller than second mold overlay 126. In other examples, first mold overlay 124 and second mold overlay 126 are substantially equal. In some examples, a portion of mold compound 122 on second side 112 of leads 104 is thicker than another portion of mold compound 122 on first side 110 of leads. 104. In some other examples, a portion of mold compound 122 on first side 110 of leads 104 is thicker than another portion of mold compound 122 on second side 112 of leads. 104. The relative values of first mold overlay 124 and second mold overlay 126 (and corresponding thickness of mold compound 122 on first side 110 and second side 112) varies according to the curvature of non-planar portion 108 of leadframe 102, and thicknesses of first device 114 and second device 118. In various examples, leadframe 102 has three leads 104, four leads 104, five leads 104, six leads 104, eight leads 104, fourteen leads 104, or sixteen leads 104. In some such examples, semiconductor package 100 varies in height between 0.6 mm to 1.45 mm and corresponding mold thickness varies between 0.55 mm to 1.2 mm. In some such examples, mold length varies between 1.6 mm to 4.2 mm; mold width varies between 1.2 mm to 2 mm.

In some examples, the material of first interconnects 116 is the same as of second interconnects 120. In some other examples, first interconnects 116 and second interconnects 120 comprise materials having different melting points. For example, first interconnects 116 comprises a low temperature solder material (e.g., solder that melts between approximately 150° C. and 230° C.) whereas second interconnects 120 comprise a high-temperature solder material (e.g., solder that melts above 230° C.), and vice versa. An example of low-temperature solder includes conventional solder (e.g., Sn63Pb37 comprising 65% tin and 35% lead) having a melting point of approximately 183° C.; an example of high temperature solder includes high-lead solder (e.g., Sn5Pb95 comprising 5% tin and 95% lead) having a melting point of approximately 350° C.

Note that the absolute melting points of first interconnects 116 and second interconnects 120 are not as significant as their relative melting points. In various examples, the melting point of first interconnects 116 is lower than the melting point of second interconnects 120. In other examples, the melting point of first interconnects 116 is higher than the melting point of second interconnects 120. For example, first interconnects 116 comprise Sn63/Pb37 solder having a melting point of approximately 183° C. and second interconnects 120 comprise any one of Sn96.5/Ag3.5 having a melting point of approximately 221° C., Sn96.5/Ag3.0/Cu0.5 (SAC305) or Sn95.5/Ag4.0/Cu0.5 (SAC405) having a melting point of approximately 217° C.-220° C. In another example, first interconnects 116 comprise Sn63/Pb37 solder having a melting point of approximately 183° C. and second interconnects 120 comprise Sn99.3/Cu0.7/Ni0.06/Ge0.005 (SN100C) having a melting point of approximately 227° C. In yet another example, first interconnects 116 comprise Sn99.3/Ag0.3/Cu0.7 (SAC0307) having a melting point of approximately 217° C.-228° C. and second interconnects 120 comprise Sn42/Bi58 having a melting point of approximately 138° C. or Sn95/Sb5 having a melting point of approximately 235° C.-240° C.

Other examples of low-temperature solder include bismuth based alloys, such as Bi—Sn (bismuth-tin, e.g., Sn-58Bi having a melting point of approximately 138° C.), Bi—Ag (bismuth-silver), Bi—Sb (bismuth-antimony) and Sn—Zn—Bi (tin-zinc-bismuth, e.g., Sn-8Zn-3Bi having a melting point of approximately 189° C.-199° C.); lead-free solders, such as Sn—Cu (tin-copper), Sn—Au (tin-gold), Sn—Ag (tin-silver, e.g., Sn96.5/3.5Ag having a melting point of approximately 221° C., Sn-2Ag having a melting point of approximately 221° C.-226° C.), Sn—Sb (tin-antimony), Sn—Ag—Cu (SAC alloys, e.g., Sn-3.8Ag-9.7Cu (SAC387) having a melting point of approximately 217° C.); indium-based solders, such as In—Sn (indium-tin, e.g., Sn-52 In having a melting point of approximately 118° C., Sn-50 In having a melting point of approximately 118° C.-125° C.), In—Bi (indium-bismuth, e.g., Bi-33 In having a melting point of approximately 109° C.), and Sn—Bi—In (tin-bismuth-indium, e.g., Sn-20Bi-10 In having a melting point of approximately 143° C.-193° C.); lead-based solders, such as Sn—Pb (tin-lead), Sn—Pb—Sb (tin-lead-antimony); and Sn—Zn (tin-zinc, e.g., Sn-9Zn having a melting point of approximately 198.5° C.) alloys, all of which have a melting point between approximately 150° C. and 230° C.). Examples of high-temperature solder include silver-based alloys, such as Ag—Cu (silver-copper) and Ag—Au (silver-gold); gold-based solders such as Au—Sn (gold-tin, e.g., Au80-Sn20 having a melting point of approximately 280° C.) and Au—Ge (gold-germanium); copper-based alloys, such as Cu—Ag (copper-silver) and Cu—Zn (copper-zinc); brazing alloys such as Cu—P (copper-phosphorus), Cu—Sn (copper-tin); leaded solder such as Sn—Pb and Sn—Pb—Sb (tin-lead-antimony, e.g., Sn5/Pb85/Sb10 having a melting point of approximately 245° C.-255° C.), Sn—Pb—Ag (tin-lead-silver, e.g., Sn5/Pb93.5/Ag1.5 having a melting point of approximately 296° C.-301° C., Sn5/Pb92.5/Ag2.5 having a melting point of approximately 299° C.-304° C.); platinum based solders, such as Pt—Sn (platinum-tin), and Pt—Ag (platinum-silver); and nickel-based alloys, such as Ni—Cr (nickel-chromium) and Ni—Sn (nickel-tin), all of which have a melting point above 230° C. Note that various alloys are named herein according to various commonly used conventions, and not in strict scientific notations.

In an example implementation comprising a six pin package (i.e., package comprising six leads), with first device 114 comprising a passive module (e.g., comprising resistor, capacitor, inductor, etc.) and second device 118 comprising a semiconductor die with power device functionalities, simulations indicated that loop inductance can be reduced by approximately 16 times compared to placing the passive module outside the package (e.g., adjacent to the pins on a printed circuit board) as shown in Table 1. In the example implementation, low parasitics connectivity from closer proximity of the passive module to the power circuits in the semiconductor die can provide lower electromagnetic interference and noise. Placing the passive module within semiconductor package 100 as described herein retains the footprint area of the package and reduces the footprint area on the PCB (e.g., by moving the passive module from the PCB into semiconductor package 100). Costs of assembly can be reduced by using a cheaper package technology and integrating surface mount processes into the manufacturing process of semiconductor package 100.

TABLE 1
Loop inductance comparison

| | Passive | | |
|---|---|---|---|
| Unit | module on PCB | Example | times of |
| (nH) | (Baseline) | implementation | reduction |
| VIN | 0.754 | 0.044 | 17.0x |
| GND | 0.645 | 0.040 | 16.1x |
| Mutual L | 0.183 | 0.0097 | |
| Loop L | 1.033 | 0.065 | 15.9x |

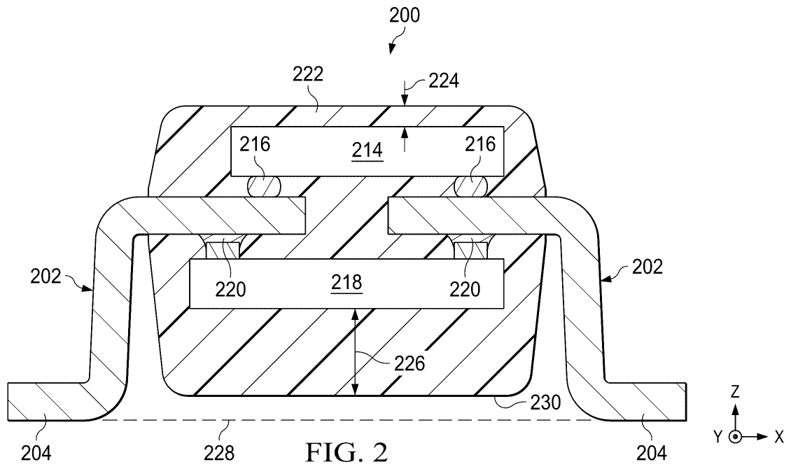

FIG. 2 is a simplified diagram illustrating a cross-sectional view of an example semiconductor package 200. Semiconductor package 200 includes a leadframe 202 comprising a plurality of leads 204. A first device 214 is mechanically coupled to leadframe 202 with first interconnects 216. A second device 218 is mechanically coupled to leadframe 202 opposite to first device 214 with second interconnects 220. A mold compound 222 covers first device 214 and second device 218 inside semiconductor package 200 such that a first mold overlay 224 is on a side of first device 214 distant from leadframe 202, and a second mold overlay 226 is on a side of second device 218 distant from leadframe 202. Although the present example shows first interconnects 216 and second interconnects 220 as solder-based, other types of interconnects, such as wirebonds may also be used without departing from the scope of the examples.

In the example shown, semiconductor package 100 is a gull-wind leaded package having a seating plane 228 that is coplanar with the tips of leads 204. In some such cases (as shown), seating plane 228 is non-coplanar with (e.g., it is offset from) a surface 230 of mold compound 222. Seating plane 228 refers to a fictitious (e.g., imaginary) reference plane on which semiconductor package 200 is placed (on a printed wiring board) during assembly. In some cases, as shown in FIG. 1, surface 230 of mold compound 222 is much closer to, or even coplanar with, seating plane 228. The offset or clearance of mold compound 222 from seating plane 228 varies according to different factors, such as curvature of leads 204, thickness of semiconductor package 200, etc.

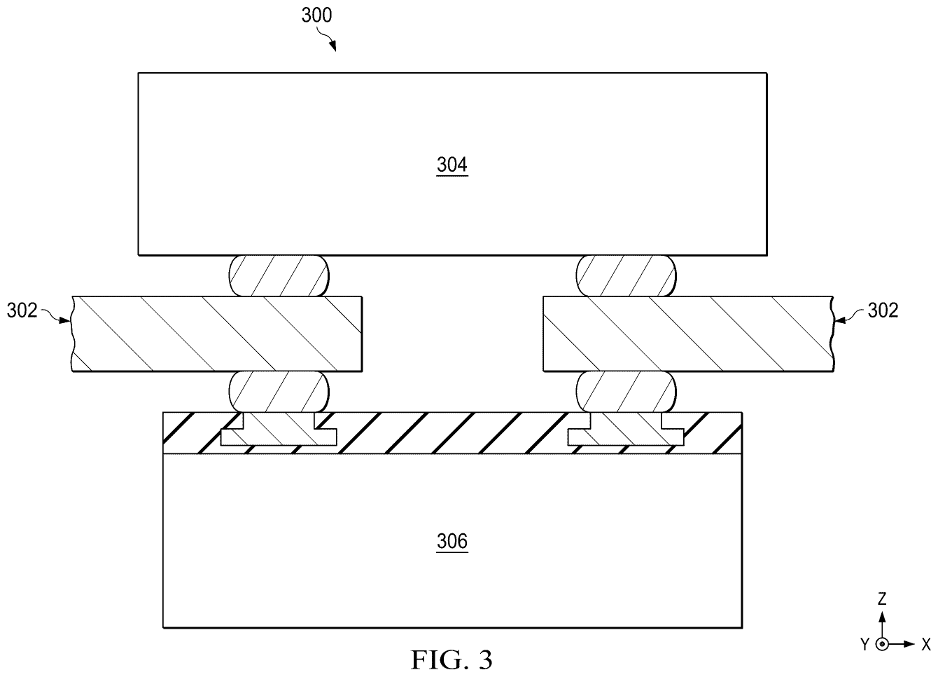

FIG. 3 is a simplified diagram illustrating a cross-sectional view of an example semiconductor package 300. Semiconductor package 300 includes a leadframe 302 to which a first device 304 is coupled on one side and a second device 306 is coupled on an opposite side. In the example shown, first device 304 is a semiconductor die and second device 306 is a Quad Flat No lead (QFN) package that includes another semiconductor die within the package (not shown for ease of illustration).

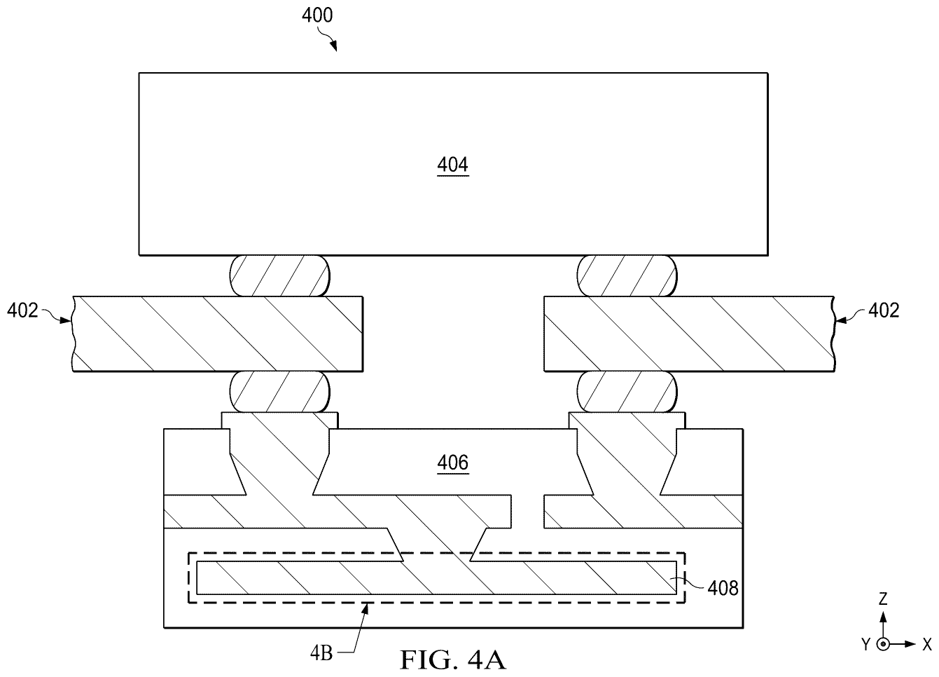

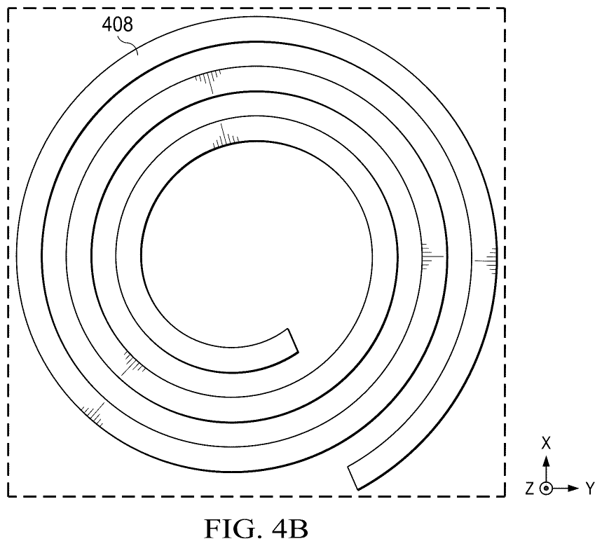

FIG. 4A is a simplified diagram illustrating a cross-sectional view of an example semiconductor package 400. Semiconductor package 400 includes a leadframe 402 to which a first device 404 is coupled on one side and a second device 406 is coupled on an opposite side. In the example shown, first device 404 is a semiconductor die and second device 406 is an organic substrate with an embedded passive component. In one example, the embedded passive component comprises an inductor 408. A plan view of inductor 408 is shown in FIG. 4B. As shown, inductor 408 comprises concentric spirals or coils of conductive material embedded in an organic dielectric material. The organic substrate further comprises multiple layers of conductive metallization and vias.

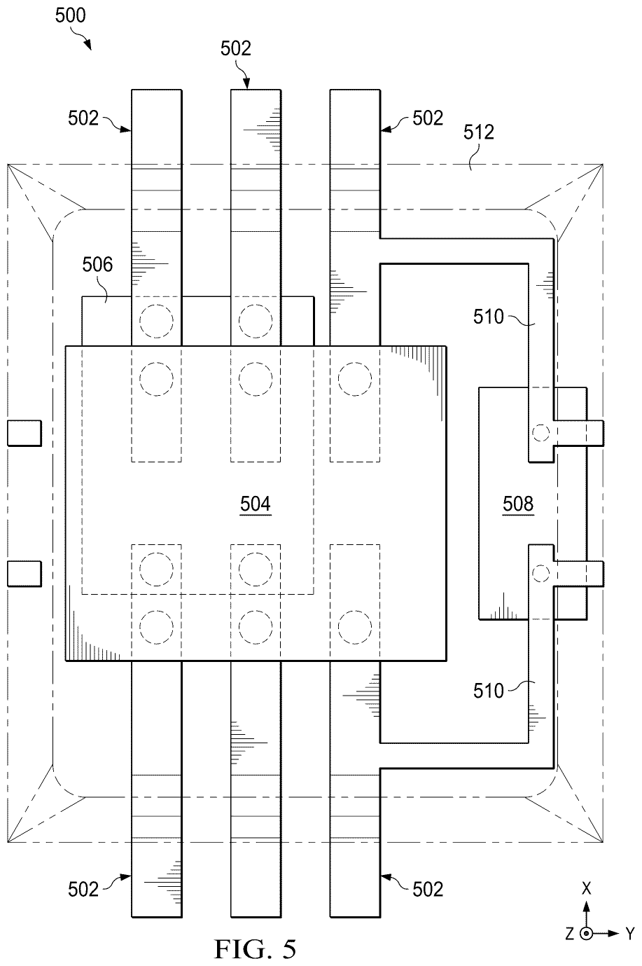

FIG. 5 is a simplified diagram illustrating a plan view of an example semiconductor package 500. Semiconductor package 500 includes a leadframe 502 to which a first device 504 is coupled on one side and a second device 506 is coupled on an opposite side. A third device 508 is coupled to tie bars 510. In some examples, tie bars 510 are narrower (e.g., thinner, having less width) than leads of leadframe 502. Semiconductor package 500 is encased in a mold compound 512. In some examples, third device 508 comprises active circuits (e.g., semiconductor die); in some other example, third device 508 does not comprise any active circuits (e.g., passive module). In some examples, tie bars 510 are mechanically coupled to only one lead in leadframe 502; in some other examples, tie bars 510 are mechanically coupled to more than one lead in leadframe 502.

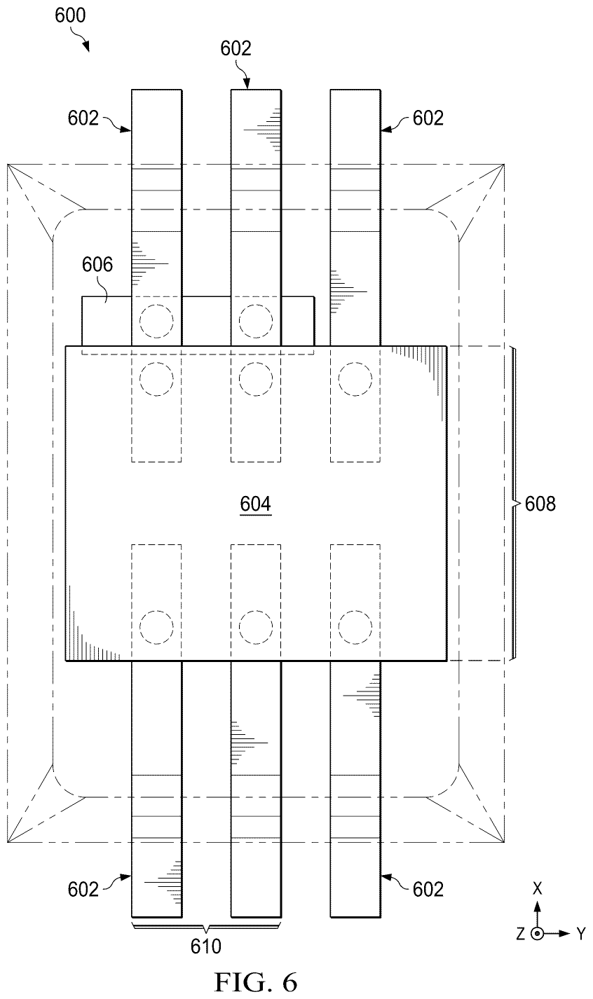

FIG. 6 is a simplified diagram illustrating a plan view of an example semiconductor package 600. Semiconductor package 600 includes a leadframe 602 to which a first device 604 is coupled on one side and a second device 606 is coupled on the opposite side. In various examples, the first device 604 is coupled to a first subset 608 of leads, and second device 606 is coupled to a second subset 610 of leads, which is different from first subset 608. In the example shown, semiconductor package 600 has six leads; all six leads are comprised in first subset 608. On the other hand, second device 606 is coupled to two of the six leads; these two leads thus comprise second subset 610. Note that leadframe 602 may have any number of leads without departing from the scope of the examples discussed herein; likewise, each subset 608 and 610 may have any number of leads based on particular needs.

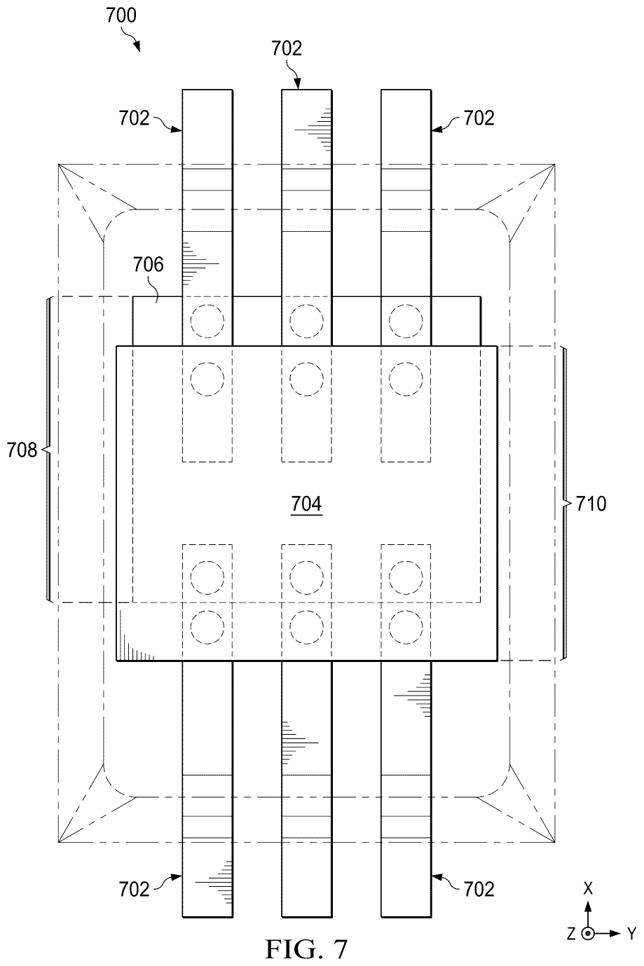

FIG. 7 is a simplified diagram illustrating a plan view of an example semiconductor package 700. Semiconductor package 700 includes a leadframe 702 to which a first device 704 is coupled on one side and a second device 706 is coupled on the opposite side. In various examples, the first device 704 is coupled to a first subset 708 of leads, and second device 706 is coupled to a second subset 710 of leads, which is the same as first subset 708. In the example shown, semiconductor package 700 has six leads; all six leads are comprised in both first subset 708 and second subset 710. Note that leadframe 602 may have any number of leads without departing from the scope of the examples discussed herein based on particular needs.

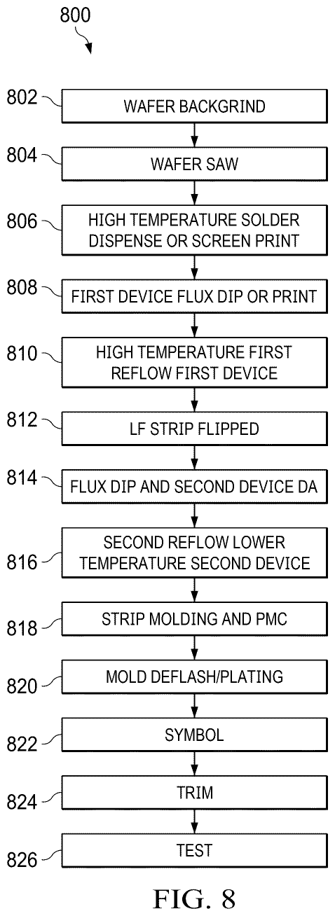

FIG. 8 is a simplified flow diagram illustrating example operations 800 associated with making (e.g., manufacturing) a semiconductor package, such as semiconductor package 100. At 802, a wafer comprising multiple ones of first device 114 is subjected to backgrind operations. At 804, the wafer is sawed into individual ones of first device 114. At 806, high-temperature solder is dispensed (e.g., screen printed, deposited, plated and bumped, etc.) suitably on one or more of first device 114. In one example, the high-temperature solder is plated on the bond-pads of first device 114 and then subjected to a reflow process to form solder bumps. In another example, the high-temperature solder is deposited on the copper pillars of first device 114 and then heated to form solder bumps on the copper pillars. At 808, flux dip or print operations are performed. At 810, a first reflow operation at the high temperature melting point of the high-temperature solder is performed to form first interconnects 116 between first device 114 and leadframe 102, which is in strip form to accommodate multiple ones of first device 114 on corresponding multiple ones of leadframe 102. The leadframe strip is flipped at 812. At 814, second device 118 is subjected to die attach using low-temperature solder and flux dip. At 816, the assembly is subjected to the low temperature melting point of the low-temperature solder. During this operation, the high-temperature solder retains its integrity due to the low-temperature that is not sufficient to melt the high-temperature solder. At 818, the assembly is subjected to strip molding and post molding cure (PMC). At 820, mold deflash and plating processes are performed. At 822, symbols and other marks are marked on the packages. At 824, the packages are trimmed and at 826, they are tested.

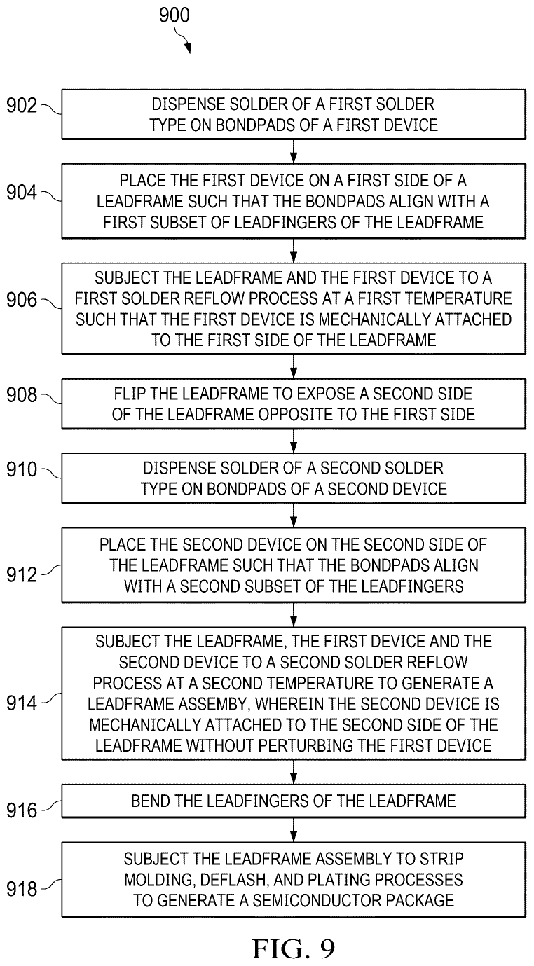

FIG. 9 is a simplified flow diagram illustrating example operations 900 associated with making (e.g., manufacturing) a semiconductor package, such as semiconductor package 100. At 902, solder of a first solder type (e.g., high-temperature solder) is dispensed (e.g., plated and bumped, screen printed, etc.) on bond-pads of first device 114. At 904, first device 114 is placed on first side 110 of leadframe 102 such that the bond-pads align with first subset 608 of leads 104 of leadframe 102. At 906, leadframe 102 and first device 114 are subjected to a first solder reflow process at a first temperature (e.g., low temperature corresponding to the melting point of the low-temperature solder) such that first device 114 is mechanically attached to first side 110 of leadframe 102 by first interconnects 116. At 908, leadframe 102 is flipped (e.g., turned) to expose second side 112 of leadframe 102 opposite to first side 110. At 910, solder of a second solder type (e.g., low-temperature solder) is dispensed (e.g., plated and bumped, screen printed, etc.) on bond-pads of second device 118. At 912, second device 118 is placed on second side 112 of leadframe 102 such that the bond-pads of second device 118 align with second subset 610 of leads 104. At 914, leadframe 102, first device 114 and second device 118 are subjected to a second solder reflow process at a second temperature (e.g., high temperature corresponding to the melting point of the high-temperature solder) to generate a leadframe assembly, such that second device 118 is mechanically attached to second side 112 of leadframe 102 by second interconnects 120 without affecting (e.g., moving, perturbing, dislocating, etc.) first device 114. In various examples, the first temperature is higher than the second temperature so that first interconnects 116 do not melt during the second reflow process. At 916, leads 104 of leadframe 102 is subjected to bending. At 918, the leadframe assembly is subjected to strip molding, deflash, and plating processes to generate semiconductor package 100.

In some examples, the first solder type and second solder type are the same. In such cases, during the second reflow process at 914, first interconnects 116 melt. The surface tension forces of the melted material would have to balance the gravitational forces acting on first device 114 to prevent first device 114 from falling off leadframe 102. In such cases, the amount of solder dispensed at 902 is selected based on the weight of first device 114 so that the surface tension forces of the solder when melted, balance the weight of first device 114. In some such examples, the operation at 906 may be avoided and the entire assembly may be subjected to a single reflow process at 914.

Although FIGS. 8-9 illustrates various operations performed in a particular order, this is simply illustrative, and the operations discussed herein may be reordered and/or repeated as suitable. Further, additional operations which are not illustrated may also be performed without departing from the scope of the present disclosure. Also, various operations discussed herein with respect to FIGS. 8-9 may be modified in accordance with the present disclosure to manufacture semiconductor package 100 as disclosed herein. Although various operations are illustrated in FIGS. 8-9 once each, the operations may be repeated as often as desired.

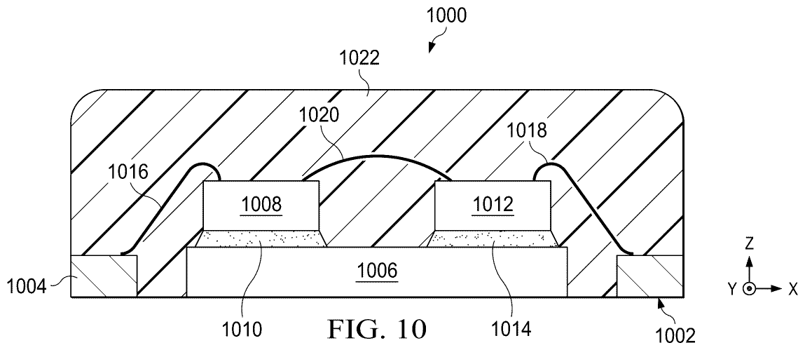

FIG. 10 is a simplified diagram illustrating a cross-sectional view of an example semiconductor package 1000. Semiconductor package 1000 includes a leadframe 1002 comprising a plurality of leads 1004 and one or more die pads 1006. In the example shown, only one of die pad 1006 is shown; however, it may be noted that any number of die pads within manufacturing limitations may be included without departing from the scope of the disclosure. Leadframe 1002 comprises conductive material, such as copper or other metals in some examples. A first device 1008 is attached to die pad 1006 by a die attach adhesive 1010. In some examples, first device 1008 is a semiconductor die. In some other examples, first device 1008 is a passive device (e.g., capacitor, resistor, inductor) without any active circuitry therein. A second device 1012 is attached to die pad 1006 by a die attach adhesive 1014. In some examples, second device 1012 may be a semiconductor die. In some other examples, second device 1012 is a passive device (e.g., capacitor, resistor, inductor) without any active circuitry therein. In some examples, die attach adhesive 1010 and 1014 are merged (e.g., comprise contiguous material). The distance between first device 1008 and second device 1012 may be based on handling, process tolerances and other process considerations beyond the scope of the present disclosure.

In the example shown, first device 1008 and second device 1012 are attached to the same side of die pad 1006. First device 1008 is connected to leads 1004 by first wires 1016. Second device 1012 is connected to leads 1004 by second wires 1018. In various examples, proximate (e.g., adjacent) sides of first device 1008 and second device 1012 are connected by third wires 1020. Although not shown so as not to clutter the drawings, first wires 1016, second wires 1018 and third wires 1020 include bond-pads on first device 1008 and second device 1012. A mold compound 1022 covers (e.g., encapsulates) first device 1008 and second device 1012 inside semiconductor package 1000. In the example shown, semiconductor package 1000 is a QFN package. Other types of leadframe based packages such as Single Outline Integrated Circuit (SOIC), gull-wing packages, and J-lead packages, may be included in the broad scope of the various modifications to the illustrated example.

In various examples, leadframe 1002 has three leads 1004, four leads 1004, five leads 1004, six leads 1004, eight leads 1004, fourteen leads 1004, or sixteen leads 1004. In some such examples, semiconductor package 1000 varies in height between 0.6 mm to 1.45 mm and corresponding mold thickness varies between 0.55 mm to 1.2 mm. In some such examples, mold length varies between 1.6 mm to 4.2 mm; mold width varies between 1.2 mm to 2 mm. In some examples (as shown), portions of leads 1004 and die pad 1006 are exposed; in other words, mold compound 1022 is not in direct contact with some portions of leads 1004 and die pad 1006. Note that in the example shown, both first device 1008 and second device 1012 are attached to the same die pad 1006. In some other examples, each of first device 1008 and second device 1012 are attached to respectively different die pads 1006 in the same or different planes. For example, one die pad 1006 is taller or at another plane compared to another die pad 1006 in semiconductor package 1000.

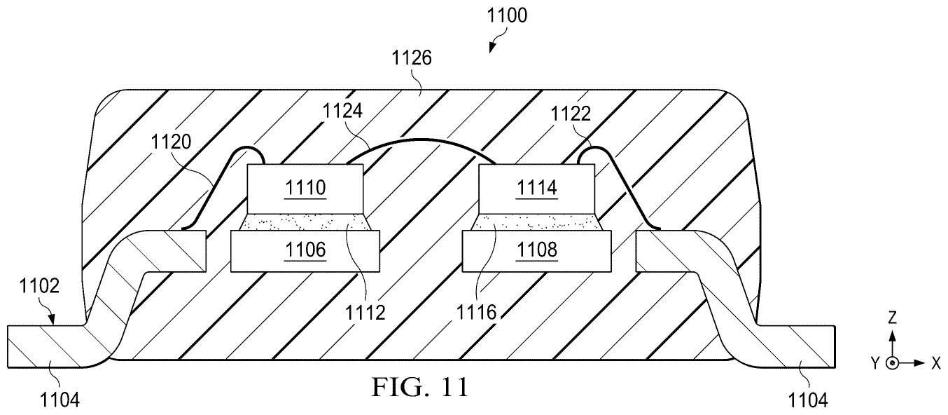

FIG. 11 is a simplified diagram illustrating a cross-sectional view of an example semiconductor package 1100. Semiconductor package 1100 includes a leadframe 1102 comprising a plurality of leads 1104 and one or more die pads 1106 and 1108. In the example shown, at least one surface each in die pads 1106 and 1108 are coplanar. In some other examples, none of the surfaces of die pads 1106 and 1108 are coplanar. Leadframe 1102 comprises conductive material, such as copper or other metals in some examples. A first device 1110 is attached to die pad 1106 by a die attach adhesive 1112. In some examples, first device 1110 is a semiconductor die. In some other examples, first device 1110 is a passive device (e.g., capacitor, resistor, inductor) without any active circuitry therein. A second device 1114 is attached to die pad 1108 by a die attach adhesive 1116. In some examples, second device 1114 is a semiconductor die. In some other examples, second device 1114 is a passive device (e.g., capacitor, resistor, inductor) without any active circuitry therein.

In the example shown, first device 1110 and second device 1114 are attached to the same side of respective die pads 1106 and 1108. First device 1110 is connected to leads 1104 by first wires 1120. Second device 1114 is connected to leads 1004 by second wires 1122. In various examples, proximate (e.g., adjacent) sides of first device 1110 and second device 1114 are connected by third wires 1124. Although not shown so as not to clutter the drawings, first wires 1120, second wires 1122 and third wires 1124 include bond-pads on first device 1110 and second device 1114. A mold compound 1126 covers (e.g., encapsulates) first device 1110 and second device 1114 inside semiconductor package 1100. In the example shown, semiconductor package 1000 is a gull-wing package. Other types of leadframe-based packages, such as QFN, SOIC, etc. may be included in the broad scope of the various modifications to the illustrated example.

In various examples, leadframe 1102 has three leads 1104, four leads 1104, five leads 1104, six leads 1104, eight leads 1104, fourteen leads 1104, or sixteen leads 1104. In some such examples, semiconductor package 1100 varies in height between 0.6 mm to 1.45 mm and corresponding mold thickness varies between 0.55 mm to 1.2 mm. In some such examples, mold length varies between 1.6 mm to 4.2 mm; mold width varies between 1.2 mm to 2 mm. In some examples, portions of leads 1104 and die pads 1106 and 1108 are exposed; in other words, mold compound 1126 is not in direct contact with some portions of leads 1104 and die pads 1106 and 1108. In some other examples (as shown), mold compound 1126 substantially directly contacts all surfaces of die pads 1106 and 1108 that are not otherwise covered by die attach adhesive 1112 or 1116 or portions of first wires 1120 or second wires 1122.

Although the present disclosure has described in detail particular arrangements and configurations, these example configurations and arrangements may be changed significantly without departing from the scope of the present disclosure. For example, although the present disclosure has been described with reference to electronic packages, the same configuration and arrangements may be applicable to other types of packages, such as optical or photonic packages that include optical or photonic devices in addition to ICs. Moreover, although the semiconductor packages have been illustrated with reference to particular elements that facilitate the power device functionalities, these elements and operations may be replaced by any other suitable architecture for other functionalities processing, such as digital signal processing, or mixed-signal processing.

It is important to note that the operations described with reference to the preceding figures illustrate only some of the possible scenarios that may be implemented to manufacture semiconductor package 100. Some of these operations may be deleted or removed where appropriate, or these steps may be modified or changed considerably without departing from the scope of the discussed concepts. In addition, the timing of these operations may be altered considerably and still achieve the results taught in this disclosure. The preceding operational flows have been offered for purposes of example and discussion.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A semiconductor package, comprising:
a plurality of leads, each lead having a planar portion and a non-planar portion, wherein:
the planar portion has a first side and a second side opposing the first side, and
the non-planar portion is at an angle with the planar portion;
a passive module mechanically coupled to the first side of the planar portion with first interconnects comprising a first material;
a semiconductor die mechanically coupled to the second side of the planar portion with second interconnects comprising a second material, the second material having a lower melting temperature than the first material; and
mold compound covering the passive module and the semiconductor die, wherein:
a first mold overlay is on a side of the passive module distant from the leads, and
a second mold overlay is on a side of the semiconductor die distant from to the leads.

2. The semiconductor package of claim 1, wherein the passive module is a one of a resistor, inductor or capacitor.

3. The semiconductor package of claim 1, wherein the passive module is an organic substrate having an embedded passive component.

4. The semiconductor package of claim 3, wherein the embedded passive component is an inductor.

5. The semiconductor package of claim 1, wherein:
the first interconnects comprise copper pillars with solder caps, and
the second interconnects comprise solder balls.

6. The semiconductor package of claim 1, wherein:
the passive module is coupled to a first subset of leads,
the semiconductor die is coupled to a second subset of leads, and
the first subset is different from the second subset.

7. The semiconductor package of claim 1, further comprising another passive module electrically and mechanically coupled to tie bars, wherein the tie bars are mechanically coupled to at least one of the leads.

8. The semiconductor package of claim 1, wherein the passive module and the semiconductor die are electrically coupled to each other through at least one lead.

9. The semiconductor package of claim 8, wherein the semiconductor die is a power metal-oxide-semiconductor field-effect transistors (MOSFET) and the passive module is at least one of a capacitor and an inductor.

10. A semiconductor package, comprising:
a leadframe comprising a plurality of leads, each lead having a planar portion and a non-planar portion, wherein:
the planar portion has a first side and a second side opposing the first side, and the non-planar portion is at an angle with from the planar portion;
a first device mechanically coupled to the first side of the planar portion with first interconnects of a first material;
a second device mechanically coupled to the second side of the planar portion with second interconnects of a second material different from the first material; and
mold compound covering the first device and the second device inside the semiconductor package.

11. The semiconductor package of claim 10, wherein the semiconductor package is a flip chip small outline (FCSOT) package and the first interconnects and the second interconnects are not wirebonds.

12. The semiconductor package of claim 10, wherein the second device is larger than the first device in a top view.

13. The semiconductor package of claim 10, wherein the second device is thicker than the first device in a cross-sectional view.

14. The semiconductor package of claim 10, wherein a portion of the mold compound on the second side of the plurality of leads is thicker than another portion of the mold compound on the first side of the plurality of leads.

15. The semiconductor package of claim 10, wherein:
the semiconductor package is a gull-wing leaded package, and
a seating plane of the plurality of leads is non-coplanar with a surface of the mold compound.

16. The semiconductor package of claim 10, wherein:
the first device is an organic substrate with an embedded passive component, and
the second device is a semiconductor die.

17. A method of making a semiconductor package, the method comprising:
dispensing solder of a first solder type on first bond-pads of a first device;
placing the first device on a first side of a leadframe such that the first bond-pads align with a first subset of leads of the leadframe;
subjecting the leadframe and the first device to a first solder reflow process at a first temperature such that the first device is mechanically attached to the first side of the leadframe;
flipping the leadframe to expose a second side of the leadframe opposite to the first side;
dispensing solder of a second solder type on second bond-pads of a second device;
placing the second device on the second side of the leadframe such that the second bond-pads align with a second subset of the leads; and
subjecting the leadframe, the first device and the second device to a second solder reflow process at a second temperature to generate a leadframe assembly, wherein the second device is mechanically attached to the second side of the leadframe without affecting the first device.

18. The method of claim 17, wherein:
the first solder type is a first solder with a first melting point,
the second solder type is a second solder with a second melting point, the first melting point higher than the second melting point, and
the first temperature is higher than the second temperature.

19. The method of claim 17, further comprising:
bending the leads of the leadframe; and
subjecting the leadframe assembly to strip molding, deflash, and plating processes to generate a semiconductor package.

20. The method of claim 19, wherein the first device comprises a passive component and the second device comprises a semiconductor die.
